(19) United States
(12) Patent Application Publication
(10) Pub. No.: US 2009/0159318 A1
(43) Pub. Date: Jun. 25, 2009

(54) Printed circuit board and manufacturing method thereof

(75) Inventors: Nobuyuki Ikeguchi, Suwon-si (KR); Eung-Suek Lee, Ansan-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/213,797

(22) Filed: Jun. 24, 2008

(30) Foreign Application Priority Data
Dec. 21, 2007 (KR) 10-2007-0134806

(51) Int. Cl. H05K 1/09; H05K 3/00

(52) U.S. Cl. 174/257; 29/843

(57) ABSTRACT

A printed circuit board and a method of manufacturing the printed circuit board are disclosed. The method may include forming at least one first bump over a first metal layer by selectively printing an alloy paste, stacking an insulation layer over the first metal layer such that the first bump penetrates the insulation layer, and stacking a second metal layer over the insulation layer. Embodiments of the invention can shorten the manufacturing process and lower manufacturing costs, while effectively implementing signal transfers.

### CROSS-REFERENCE TO RELATED APPLICATIONS

This application claims the benefit of Korean Patent Application No. 10-2007-0134806 filed with the Korean Intellectual Property Office on Dec. 21, 2007, the disclosure of which is incorporated herein by reference in its entirety.

### BACKGROUND

1. Technical Field

The present invention relates to a printed circuit board and to a method of manufacturing the printed circuit board.

2. Description of the Related Art

Current electronic devices are trending towards smaller, thinner, and lighter products. In step with these trends, the preferred methods for mounting semiconductor chips are changing from wire bonding methods to flip chip methods, which allow a greater number of terminals. As such, there is a demand also that the printed circuit board, to which the semiconductor chips may be mounted, be provided as a multilayer printed circuit board having higher densities and resistance to heat, as well as a demand for lower costs. Various methods are being developed that respond to these demands.

FIG. 1 is a cross sectional view illustrating a printed circuit board according to the related art. In a printed circuit board manufactured by performing copper plating over the walls of the through-holes, as illustrated in the drawing, if the diameter of a through-hole or a blind via hole exceeds 100 μm, it can be difficult to fill the hole by copper plating, and thus plating voids may be present.

One method of resolving this difficulty is to have the copper plating formed over only the walls of the holes which can then be connected with the copper circuits on the surfaces, instead of filling up the holes with the copper plating. In this case, however, the lands may not be formed directly over the holes, so that the lands which connect with an upper layer may have to be formed away from above the holes. This can lead to an increase in circuit-forming area, and can thus pose an obstacle to reducing size.

If the through-holes or blind via holes have diameters smaller than 100 μm, or even 60 μm, it may be possible to fill the insides of the holes with copper plating, but this may require a long duration of time and thus lower productivity.

To respond to these difficulties, various types of build-up printed circuit boards are being developed. One method of forming the printed circuit board includes filling the copper plated through-holes with a supplementary resin composition, leveling the surface by grinding, and then applying a copper plating again over the surface. Afterwards, small-diameter blind via holes can be formed over lands fabricated over the supplemented resin composition, and the holes can be filled with copper plating, the procedures of which can be repeated to implement multiple layers.

To prevent the copper clad laminate from being ground to below a desired thickness during the grinding of the supplementary resin composition at the surface, the copper clad laminate may be increased in thickness. Due to this high rate of change in the dimensions of the copper clad laminate, there can be difficulties in manufacturing the printed circuit board to a high density.

Furthermore, the increase in manufacturing process may raise costs, making the process uneconomical. Also, as the building up of each layer is achieved by individual stacking and circuit-forming, the manufacturing process can be prolonged. If numerous layers are built up, the increase in time and cost may lead to lower productivity and lower cost effectiveness.

Other methods for manufacturing-multilayer printed circuit boards are also being developed, including those of B2it (buried bump interconnection technology), which connect all of the layers using a silver paste composition. However, since the resistivity of silver paste, which is about 5×10⁻⁴ Ω·cm, is greater than the resistivity of copper, which is about 1.7×10⁻⁶ Ω·cm, these may not be suitable for signal transfers in certain applications. In addition, silver is subject to migration, which can incur problems in reliability.

### SUMMARY

An aspect of the invention provides a method of manufacturing a printed circuit board that can shorten the manufacturing process and lower manufacturing costs, while effectively implementing signal transfers.

Another aspect of the invention provides a method of manufacturing a printed circuit board, where the method includes forming at least one first bump over a first metal layer by selectively printing an alloy paste, stacking an insulation layer over the first metal layer such that the first bump penetrates the insulation layer, and stacking a second metal layer over the insulation layer.

After the operation of stacking the second metal layer, the first metal layer can be selectively etched to form an inner circuit electrically connected with the first bump.

In certain embodiments, the method may further include hot pressing the first metal layer and the second metal layer, and forming an outer circuit electrically connected with the first bump by selectively etching the second metal layer, after the operation of stacking the second metal layer.

The alloy paste can be such that solidifies within a temperature range of 150 to 400° C.

After the forming of the outer circuit, the method of manufacturing a printed circuit board can further include forming at least one second bump over the insulation layer, on which the outer circuit is formed, by selectively printing an alloy paste; and stacking a build-up layer over the insulation layer such that the second bump penetrates the build-up layer.

The operations of forming the second bump and stacking the build-up layer can be performed repeatedly.

The alloy paste can include lead-free solder, and can be made from at least one element selected from a group consisting of tin, copper, nickel, silver, bismuth, and indium.

Also, the first bump can be formed from metal particles having diameters of 0.1 to 10 μm, and can be formed in one of a conical shape and a trapezoidal shape.

Yet another aspect of the invention provides a printed circuit board that includes an insulation layer, a bump penetrating the insulation layer, an inner circuit electrically connected with the bump formed over one side of the insulation layer, and an outer circuit electrically connected with the bump formed over the other side of the insulation layer, where the bump is formed from an alloy paste.

The alloy paste can include lead-free solder, and can be made from at least one element selected from a group consisting of tin, copper, nickel, silver, bismuth, and indium.

The alloy paste can be such that solidifies within a temperature range of 150 to 400° C.

Also, the bump can include metal particles having diameters of 0.1 to 10 μm, and can be formed in one of a conical shape and a trapezoidal shape.

Additional aspects and advantages of the present invention will be set forth in part in the description which follows, and in part will be obvious from the description, or ay be learned by practice of the invention.

### BRIEF DESCRIPTION OF THE DRAWINGS

FIG. 1 is a cross sectional view illustrating a printed circuit board according to the related art.

FIG. 2 is a flowchart illustrating a method of manufacturing a printed circuit board according to an embodiment of the invention.

FIG. 3, FIG. 4, FIG. 5, FIG. 6, FIG. 7, FIG. 8, and FIG. 9 are cross sectional views representing a flow diagram for a method of manufacturing a printed circuit board according to an embodiment of the invention.

FIG. 10 and FIG. 11 are cross sectional views representing a flow diagram for a method of manufacturing a printed circuit board according to another embodiment of the invention.

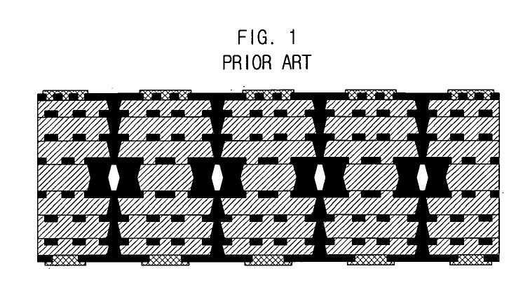

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first,” “second,” etc., may be used to describe various elements, such elements must not be limited to the above terms. The above terms are used only to distinguish one element from another.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

Certain embodiments of the invention will be described below in more detail with reference to the accompanying drawings.

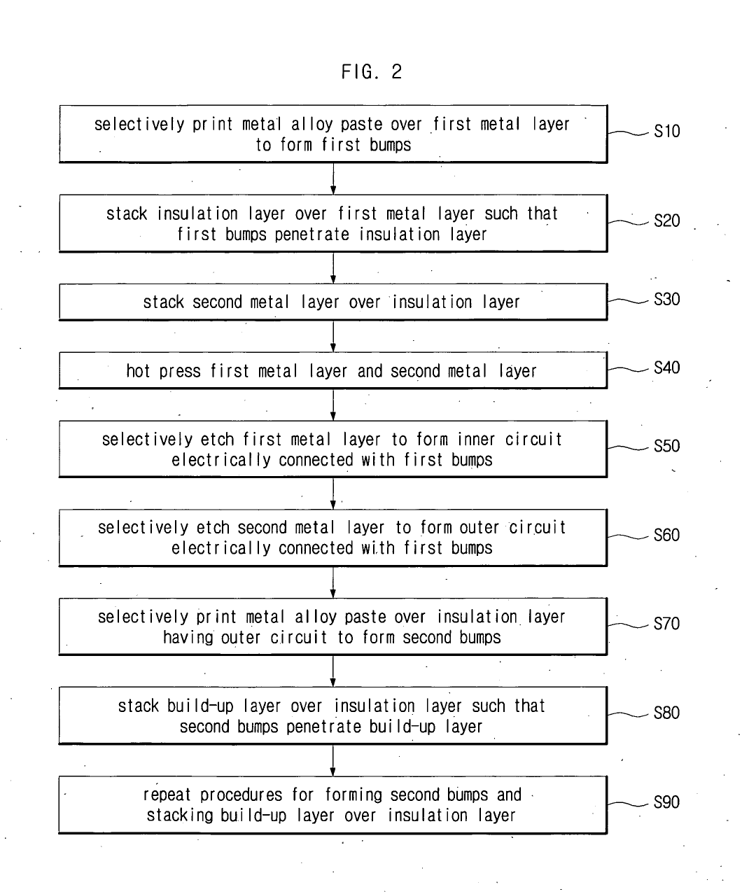

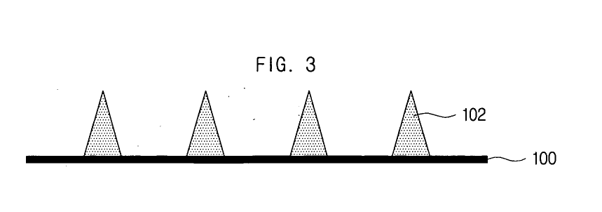

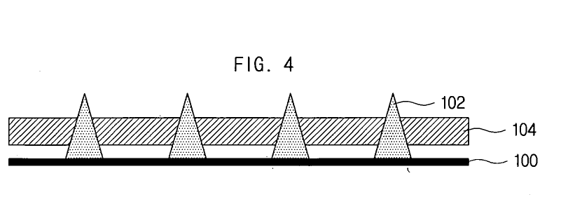

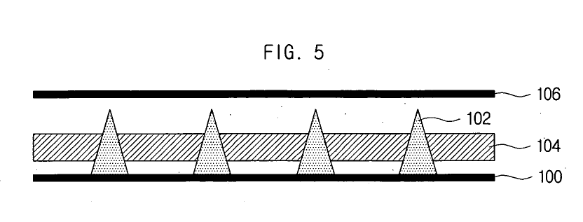

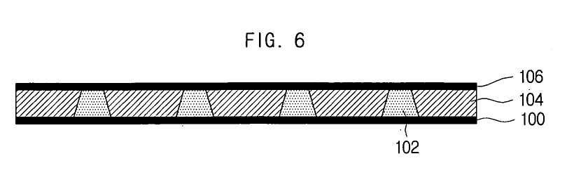

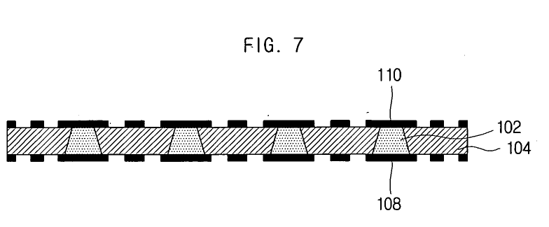

FIG. 2 is a flowchart illustrating a method of manufacturing a printed circuit board according to an embodiment of the invention, and FIGS. 3 to 9 are cross sectional views representing a flow diagram for a method of manufacturing a printed circuit board according to an embodiment of the invention.

In this embodiment, the method of electrically interconnecting circuit layers in manufacturing a multilayer printed circuit board can include the forming of interconnection bumps using a metal alloy. This may improve conduction between layers within the board.

First, as illustrated in FIG. 3, an alloy paste may be selectively printed over a first metal layer 100 to form first bumps 102 (S10). Here, the alloy paste can be an alloy of a lead-free solder that contains metals such as tin, copper, nickel, silver, bismuth, and indium. A flux may or may not be used.

The solder paste, which may later be made into conical first bumps 102, can be made from substantially spherical small-diameter alloy particles, for example, having an average diameter of 0.1 to 10 μm, where a binder can be added to form a paste. In certain embodiments, the first bumps 102 can be made from alloy particles having diameters of 1 to 25 μm. The alloy particles can be mixed into a solvent having a boiling point between the solidus and liquidus temperatures of the alloy particles, to form a paste of a desired viscosity.

The prepared paste can be formed into conical first bumps 102 using a screen-printing method. The first bumps 102 can be formed to a rigidity sufficient to penetrate an insulation layer 104, by heating the solvent to above its boiling point. In this case, the oxide layers on the surfaces of the alloy particles may be almost entirely removed, and portions of the spherical alloy particles may attach to one another and maintain conical shapes.

Forming the conical first bumps 102 according to this embodiment is not limited to the method described above, and various other methods may also be employed. For example, one method may include the use of alloy particles having a liquidus temperature of 270° C. The alloy particles can be melted at a temperature above 270° C., attached to the copper layer, and formed into bumps during the cooling of the alloy particles.

The shape of the first bumps 102 can be conical or trapezoidal. In certain embodiments, the first bumps 102 can be fabricated using bumps made of a lead-free alloy by way of a B2it process. Also, through-holes may be processed beforehand over the insulation layer 104, which will be described later in more detail, and afterwards the first bumps 102 may be printed over the through-holes.

In this particular embodiment, the alloy paste may include tin and copper. The alloy paste may be such that has a solidus of 150° C. and a liquidus of 400° C. In another embodiment, an alloy paste can be used that has a solidus of 200° C. and a liquidus of 270° C.

Here, the solidus temperature refers to the temperature at which the solidifying of an alloy is completed, while the liquidus temperature refers to the temperature at which the solidifying of an alloy is initiated. Therefore, the alloy paste in this particular embodiment can solidify within a temperature range of 150 to 400° C. If the solidifying temperature is below 150° C. or above 400° C., it can be difficult to form the conical bumps.

Next, as illustrated in FIG. 4, the insulation layer 104 can be stacked over the first metal layer 100 such that the first bumps 102 penetrate the insulation layer 104 (S20), and as illustrated in FIG. 5, a second metal layer 106 can be stacked over the insulation layer 104 (S30). The second metal layer 106 may or may not be formed from the same type of alloy as that of the first metal layer 100.

Here, the insulation layer 104 can be made of a material such as an insulating B-stage thermosetting resin, a copper-clad insulating B-stage thermosetting resin, prepreg, a heat-resistant insulating thermoplastic resin, and an insulating radical-setting polymer resin, etc.

The insulation layer 104 can include polypropylene glycol or an insulation film. The stacking of the insulation layer 104 can employ a laminator or a press, etc., to force the first bumps 102 to penetrate the insulation layer 104. Of course, this process may also employ B2it methods and equipment, which may include printing the alloy paste bumps to implement interlayer connections.

Next, as illustrated in FIG. 6, the first metal layer 100 and the second metal layer 106 can be hot pressed together (S40). To be more specific, in one example, a rigid flat plate of stainless steel can be formed over the second metal layer 106 and pressed in a vacuum while the temperature is raised to or above the solidus temperature of the alloy. The pressing, can include, for example, stacking and molding at a temperature of 280 to 350° C. and a pressure of 1 to 50 kgf/cm² for 1 to 60 minutes, in a vacuum of 10 mmHg or lower. In this case, the alloy used may have a liquidus temperature above the stacking temperature.

Next, as illustrated in FIG. 7, the first metal layer 100 can be selectively etched to form an inner circuit 108 electrically connected with the first bumps 102 (S50), and the second metal layer 106 can be selectively etched to form an outer circuit 110 electrically connected with the first bumps 102 (S60).

As the first bumps 102 are formed from an alloy paste, the electrical conductivity of the board can be improved, and the absence of lead in the bumps can provide a more environment-friendly quality. The inner circuit 108 and outer circuit 110 may be formed in the respective metal layers using a subtractive or semi-additive method.

Next, as illustrated in FIG. 8, an alloy paste can be selectively printed over the insulation layer 104, on which the outer circuit 110 is formed, to form second bumps 112 (S70). Of course, the second bumps 112 can be made of substantially the same material as that of the first bumps 102, and can be implemented using substantially the same method as that for forming the first bumps 102.

That is, the alloy paste can be printed again over the insulation layer 104, on which the outer circuit 110 is formed, to form the second bumps 112, i.e. alloy paste bumps. Similar to the case of the alloy paste bumps and the inner circuit described above, the second bumps 112 can be formed in positions that allow electrical connection to the outer circuit 110.

Next, a build-up layer 114 can be stacked over the insulation layer 104 such that the second bumps 112 penetrate the build-up layer 114 (S80). Here, the build-up layer 114 can be of the same type as the insulation layer 104 described above, and represents the stacking of the insulation layer 104 in multiple numbers.

Next, the forming of the second bumps 112 and the stacking of the build-up layer 114 over the insulation layer 104 can be repeated (S90). By repeating these operations, a multilayer printed circuit board can be formed, as in the example illustrated in FIG. 8. Next, as illustrated in FIG. 9, the second bumps 112 formed over multiple layers of circuit patterns and the multiple layers of build-up layers 114 can be pressed together to form a multilayer printed circuit board. The bumps formed from a metal alloy can effectively transfer electrical signals between the inner circuits 108 and outer circuits 110 of the multilayer printed circuit board and can improve adhesion between the layers of the board. The metal alloy forming the bumps can be a lead-free alloy and can thus be more environment-friendly.

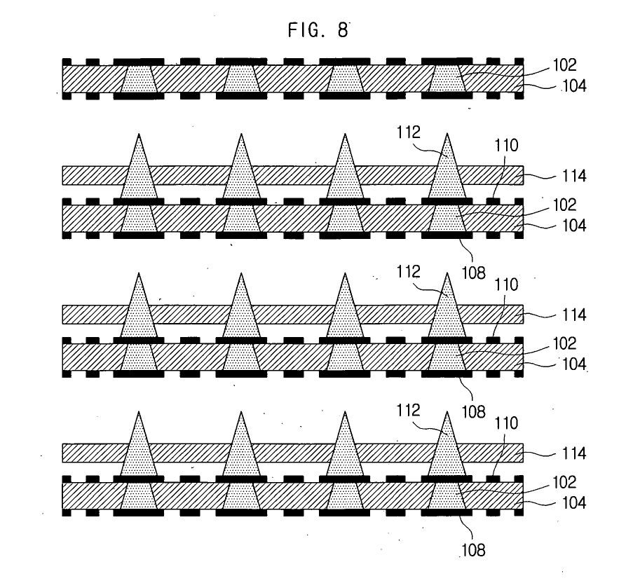

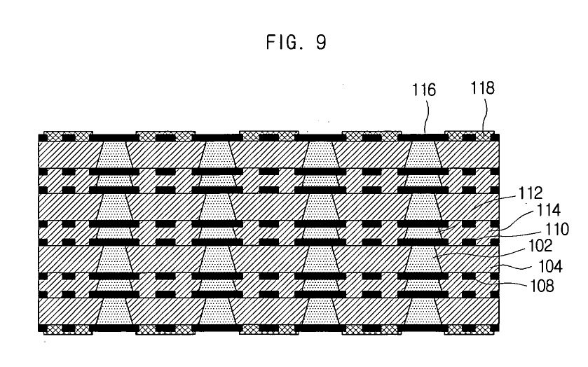

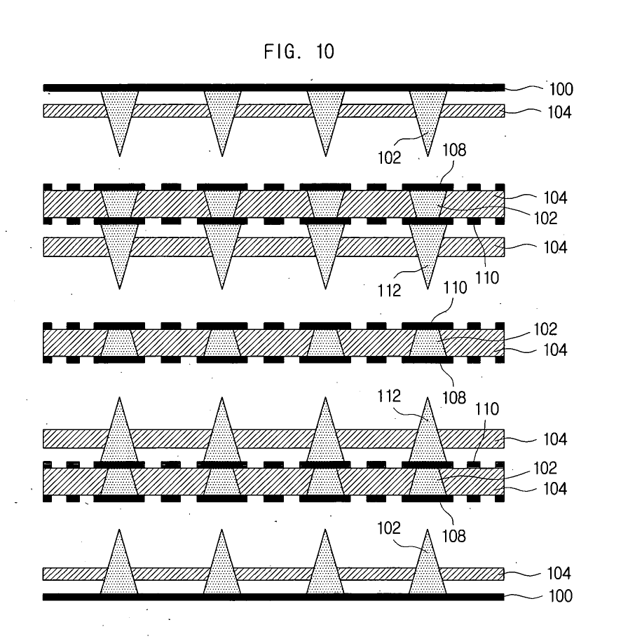

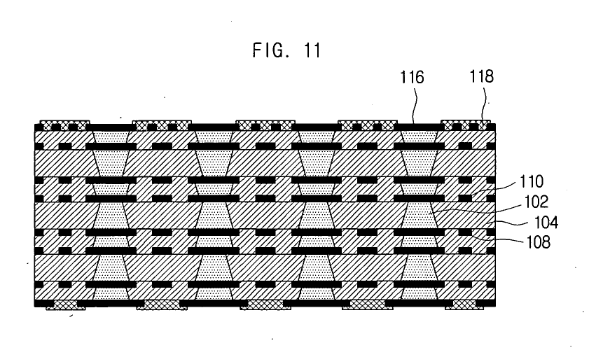

FIGS. 10 and 11 are cross sectional views representing a flow diagram for a method of manufacturing a printed circuit board according to another embodiment of the invention. In the method of manufacturing a printed circuit board illustrated in FIGS. 10 and 11, the basic board can be formed by substantially the same method as that represented in FIGS. 3 to 7, but the subsequent build-up process may differ from the embodiment described previously. The following will elaborate on this difference.

As in the example illustrated in FIG. 7, an inner circuit 108 and an outer circuit 110 can be formed that are electrically connected with first bumps 102 penetrating the insulation layer 104. Next, as illustrated in FIG. 10, build-up boards may be pressed on with the board illustrated in FIG. 7 positioned in the center. Instead of forming bumps over the inner circuit 108 and outer circuit 110, the pointed ends of the conical bumps on other boards can be made to face the inner circuit 108 and outer circuit 110. In this way, a multilayer printed circuit board can be formed, such as that illustrated in FIG. 11.

### IMPLEMENTATION EXAMPLE

For solder particles (diameters 5 to 15 μm) of an alloy 94.8Sn/1.2Ag/4.0Cu (solidus 217° C., liquidus 353° C.), n-tetra decane was added to form a paste. Afterwards, a stainless steel plate was adhered over an 18 μm electro-deposited copper layer in positions where through-holes are to be formed. Then, after performing screen-printing, the stainless steel plate was removed and conical bumps were formed. Most of the n-tetra decane was removed by heating to a temperature of 240° C., resulting in conical bumps of 150 μm in lower diameter and 194 μm in height.

The bumps were made to penetrate a prepreg material, and electro-deposited copper layers were stacked and pressed onto each surface. Circuit patterns were formed in the electro-deposited copper layers formed on either side of the prepreg using a subtractive method.

### COMPARATIVE EXAMPLE

An electroless-plated copper layer of 1 μm thickness was attached in each of the through-holes, and the insides of the through-holes were filled in by copper electroplating. Circuit patterns were formed under substantially the same conditions as those for the Implementation Example.

TABLE 1

| | Presence of Voids in | | Electrical Resistance of |
|---|---|---|---|
| | Through-Holes of Inner | Roughness in Surfaces of | Inner Layer Board Between |
| | Layer Board | Through-Holes (μm) | Through-Holes (Ω) |
| Implementation | No | less than 3 | 1 × 10¹¹ |
| Example | | | |
| Comparative | Yes | 9.1 | 8 × 10¹⁰ |
| Example | | | |

In the case where electroless copper plating was used, instead of forming bumps from a metal alloy, voids occurred in the through-holes of the inner boards, the roughness was greater at the surfaces of the through-holes, and the electrical resistance in the inner layer board between through-holes was lower.

A description will now be provided on a printed circuit board according to an aspect of the invention with reference to FIG. 9. In the drawings are illustrated first bumps 102, insulation layers 104, inner circuits 108, outer circuits 110, second bumps 112, build-up layers 114, lands 116, and solder resists 118.

The first bumps 102 may penetrate the insulation layer 104. The first bumps 102 can be formed from a lead-free solder, which can include materials such as tin, copper, nickel, silver, bismuth, and indium, by performing screen-printing. The absence of lead in the first bumps 102 can be more advantageous in terms of reducing pollution. The bumps formed from an alloy paste can facilitate the transfer of electrical signals between circuit patterns and can improve adhesion between the insulation layers 104.

The solder paste, which may later be made into conical first bumps 102, can be made from substantially spherical small-diameter alloy particles, for example, having an average diameter of 0.1 to 10 μm, where a binder can be added to form a paste. In certain embodiments, alloy particles of 1 to 25 μm diameters can be used. The alloy particles can be mixed into a solvent having a boiling point between the solidus and liquidus temperatures of the alloy particles, to form a paste of a desired viscosity.

The prepared paste can be formed into conical first bumps 102 using a screen-printing method. The first bumps 102 can be formed to a rigidity sufficient to penetrate an insulation layer 104, by heating the solvent to above its boiling point. In this case, the oxide layers on the surfaces of the alloy particles may be almost entirely removed, and portions of the spherical alloy particles may attach to one another and maintain conical shapes.

The shape of the first bumps 102 can be conical or trapezoidal. In certain embodiments, the first bumps 102 can be fabricated using bumps made of a lead-free alloy by way of a B2it process. Also, through-holes may be processed beforehand over the insulation layer 104, which will be described later in more detail, and afterwards the first bumps 102 may be printed over the through-holes.

The alloy paste may be such that solidifies within a temperature range of 150 to 400° C. If the solidifying temperature is below 150° C. or above 400° C., it can be difficult to form the conical bumps.

An inner circuit 108 can be formed on one side of the insulation layer 104 and be electrically connected with the first bumps 102, while an outer circuit 110 can be formed on the other side of the insulation layer 104 and also be electrically connected with the first bumps 102.

Second bumps 112 may electrically connect the outer circuit 110 with the inner circuit of a build-up layer 114.

On the outer layers of the build-up layers 114, lands 116 may be formed, to which terminals may be attached, and solder resists 118 may be formed, which may protect the insulation layer 104 and circuit.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a printed circuit board, the method comprising:
forming at least one first bump over a first metal layer by selectively printing an alloy paste;
stacking an insulation layer over the first metal layer such that the first bump penetrates the insulation layer; and
stacking a second metal layer over the insulation layer.

2. The method of claim 1, further comprising, after the stacking of the second metal layer:
forming an inner circuit by selectively etching the first metal layer, the inner circuit electrically connected with the first bump.

3. The method of claim 1, further comprising, after the stacking of the second metal layer:
hot pressing the first metal layer and the second metal layer; and
forming an outer circuit by selectively etching the second metal layer, the outer circuit electrically connected with the first bump.

4. The method of claim 1, wherein the alloy paste solidifies within a temperature range of 150 to 400° C.

5. The method of claim 3, further comprising, after the forming of the outer circuit:
forming at least one second bump over the insulation layer having the outer circuit formed thereon by selectively printing an alloy paste; and
stacking a build-up layer over the insulation layer such that the second bump penetrates the build-up layer.

6. The method of claim 5, wherein the forming of the second bump and the stacking of the build-up layer are performed repeatedly.

7. The method of claim 1, wherein the alloy paste includes lead-free solder.

8. The method of claim 1, wherein the alloy paste includes at least one selected from a group consisting of tin, copper, nickel, silver, bismuth, and indium.

9. The method of claim 1, wherein in the forming of the first bump,
the first bump is formed from metal particles having diameters of 0.1 to 10 μm.

10. The method of claim 1, wherein in the forming of the first bump,
the first bump is formed in one of a conical shape and a trapezoidal shape.

11. A printed circuit board-comprising:
an insulation layer;
a bump penetrating the insulation layer;
an inner circuit formed over one side of the insulation layer, the inner circuit electrically connected with the bump; and
an outer circuit formed over the other side of the insulation layer, the outer circuit electrically connected with the bump;
wherein the bump is formed from an alloy paste.

12. The printed circuit board of claim 11, wherein the alloy paste includes lead-free solder.

13. The printed circuit board of claim 11, wherein the alloy paste includes at least one selected from a group consisting of tin, copper, nickel, silver, bismuth, and indium.

14. The printed circuit board of claim 11, wherein the alloy paste solidifies within a temperature range of 150 to 400° C.

15. The printed circuit board of claim ˜11, wherein the bump includes metal particles having diameters of 0.1 to 10 μm.

16. The printed circuit board of claim 11, wherein the bump is formed in one of a conical shape and a trapezoidal shape.
